(19) United States
(12) Patent Application Publication
(10) Pub. No.: US 2025/0133724 A1
(43) Pub. Date: Apr. 24, 2025

(54) MEMORY DEVICE HAVING HEXAGONAL MEMORY CELLS WITH GATE-ALL-AROUND TRANSISTORS

(71) Applicant: Micron Technology, Inc., Boise, ID (US)

(72) Inventor: Fatma Arzum Simsek-Ege, Boise, ID (US)

(21) Appl. No.: 18/777,342

(22) Filed: Jul. 18, 2024

Related U.S. Application Data
(60) Provisional application No. 63/544,701, filed on Oct. 18, 2023.

(51) Int. Cl. H10B 12/00; H01L 25/00; H01L 25/065; H01L 25/18; H10B 80/00

(52) U.S. Cl. CPC H10B 12/33; H01L 25/0657; H01L 25/18; H01L 25/50; H10B 12/05; H10B 12/482; H10B 80/00

(57) ABSTRACT

A variety of applications can include a memory device having an array of memory cells arranged as hexagonal cells, with each of the memory cells having a gate-all-around (GAA) transistor coupled to a capacitor. Digit lines to the memory cells can be arranged angled relative to the set of access lines at an angle different from ninety degrees. Digit shield lines can be structured between adjacent digit lines. The memory device can be arranged in a wafer-to-wafer interconnect architecture with the array on an array wafer connected to and below a control circuitry wafer in a circuit over array architecture.

### PRIORITY APPLICATION

This application claims the benefit of priority to U.S. Provisional Application Ser. No. 63/544,701, filed Oct. 18, 2023, which is incorporated herein by reference in its entirety.

### FIELD OF THE DISCLOSURE

Embodiments of the disclosure relate generally to integrated circuits, and more specifically, to memory devices and formation thereof.

### BACKGROUND

Memory devices are typically provided as internal, semiconductor, integrated circuits (ICs) in computers or other electronic devices. There are many different types of memory, including volatile and non-volatile memory. Volatile memory requires power to maintain its data, and includes random-access memory (RAM), dynamic random-access memory (DRAM), static RAM (SRAM), or synchronous dynamic random-access memory (SDRAM), among others. Non-volatile memory can retain stored data when not powered and includes flash memory, read-only memory (ROM), electrically erasable programmable ROM (EEPROM), erasable programmable ROM (EPROM), resistance-variable memory, such as phase-change random-access memory (PCRAM), resistive random-access memory (RRAM), magnetoresistive random-access memory (MRAM), or three-dimensional (3D) XPoint™ memory, among others. Properties of memory devices and other electronic devices can be improved by enhancements to the design and fabrication of components of the electronic devices such as, but not limited to, memory devices in an IC for the electronic devices.

### BRIEF DESCRIPTION OF THE DRAWINGS

The drawings, which are not necessarily drawn to scale, illustrate generally, by way of example, but not by way of limitation, various embodiments discussed in the present document.

FIG. 1 illustrates a cross-sectional view of a representation of components of a dynamic random-access memory device having a circuit over array architecture, where memory cells of the array can include a gate-all-around transistor coupled to a capacitor, in accordance with various embodiments.

FIG. 2 is a presentation of an arrangement of a memory cell having an access transistor and a capacitor that can be implemented in the dynamic random-access memory device of FIG. 1, in accordance with various embodiments.

FIG. 3 is a flow diagram of features of an example method of forming a memory device, in accordance with various embodiments.

FIGS. 4-22 illustrate an example method of forming a memory device having an array of hexagonal memory cells in a wafer-to-wafer interconnect architecture such as the dynamic random-access memory device of FIG. 1, in accordance with various embodiments.

FIG. 23 is a flow diagram of features of an example method of forming a memory device, in accordance with various embodiments.

FIG. 24 is a schematic of an electrical arrangement of components of an embodiment of an example dynamic random-access memory device that can include an architecture having hexagonal memory cells with gate-all-around transistors, in accordance with various embodiments.

### DETAILED DESCRIPTION

The following detailed description refers to the accompanying drawings that show, by way of illustration, various embodiments that can be implemented. These embodiments are described in sufficient detail to enable those of ordinary skill in the art to practice these and other embodiments. Other embodiments can be utilized, and structural, logical, mechanical, and electrical changes can be made to these embodiments. The term “horizontal” as used in this application is defined as a plane parallel to a conventional plane or surface of a wafer or substrate, regardless of the orientation of the wafer or substrate. The term “vertical” refers to a direction perpendicular to the horizontal as defined above and can be in a direction from the horizontal or to the horizontal. Various features can have a vertical component to the direction of their structure. The various embodiments are not necessarily mutually exclusive, as some embodiments can be combined with one or more other embodiments to form new embodiments. The following detailed description is, therefore, not to be taken in a limiting sense.

In various embodiments, a memory device can be structured with an array of memory cells arranged as hexagonal cells, where each of the memory cells has a gate-all-around (GAA) transistor coupled to a capacitor. A hexagonal memory cell is a memory cell that is surrounded by six other memory cells such that the other memory cells are at vertices of a hexagonal structure formed by connecting the centers of adjacent memory cells of these other memory cells. A GAA transistor is a transistor structured with the gate of the transistor coupled with the channel structure of the transistor on all sides of the channel structure. The GAA structure can allow a critical dimension (CD) down to approximately five nm. The GAA transistor can be structured in a pillar arrangement containing active areas (source and drain) and the channel structure about which the gate is structured around. The pillar structure of the GAA transistor can be structured as a semiconductor nanowire. Nanowires are nanostructures having a diameter on the order of nanometers. A GAA nanowire transistor as an access device to a capacitor in memory cells of a DRAM can provide enhanced ION capability and flexible adjustment of transistor threshold voltage (VT). ION is the on-state current of the transistor, where the current, IOFF, is the off-state current of the transistor. The ratio, ION/OFF, is a figure of merit for high performance and low leakage power for the transistor. High performance is associated with more ION and low leakage power is associated with less IOFF.

The memory device, having hexagonal memory cells of GAA transistors, can be implemented with control logic and sensing circuitry located above the memory arrays in a circuit over array (CoA) architecture. The control logic and sensing circuitry can be arranged for sensing the programmed data states of memory cells of one or more memory arrays of the memory device and can enhance reduction of die size or increase utilization of space in a die or combination of dies. CoA refers generally to circuitry located in a memory die over a memory array of the memory die. With the control logic and sensing circuitry fabricated over the memory array using semiconductor processing that can include CMOS (Complementary Metal Oxide Semiconductor) processing technology, CoA can also be referred to as CMOS over array. The CoA architecture can be implemented with a wafer-to-wafer architecture, where the control logic and sensing circuitry is formed on one wafer and the one or more memory arrays are formed on another wafer, with the two wafers combined. Wafer-to-wafer interconnect architectures can include a wafer-on-wafer architecture. Wafer-to-wafer bonding of back-to-back wafers in a CoA architecture can provide for the movement of a capacitor module for data storage in a DRAM to the bottom of the stack of wafers. This arrangement can reduce interconnect congestion between the stacked wafers. Alternatively, other design considerations can be implemented with such memory arrays using a circuit under array (CuA) architecture.

The memory device can include a set of access lines, where each access line of the set of access lines can be coupled to gates of a first set of multiple GAA transistors of the memory cells of a memory array. With a two-sided access line to GAA transistors of memory cells, control of the access line resistance-capacitance (RC) of directly adjacent access lines can be attained. The memory device can include a set of digit lines, where each digit line of the set of digit lines can be coupled to a second set of multiple GAA transistors of the memory cells. The set of digit lines can be angled relative to the set of access lines at an angle different from ninety degrees, where the relative orientation can be viewed with the access lines and the digit lines projected onto the same plane. Control of the digit line RC of directly adjacent digit lines can be attained with digit shield lines between the digit lines. The digit shield lines can be arranged as conductive lines. The conductive shield lines can be metal digit shield lines.

The memory device can have a 4F² memory array configuration. Memory cell sizes are measured using an nF² formula where ‘n’ is a constant derived from the cell design and ‘F’ is the feature size of the process technology. For the same feature size, as the cell size becomes smaller, memory capacity increases. In a 4F² memory cell, the access line pitch and the digit line pitch can equal 2F.

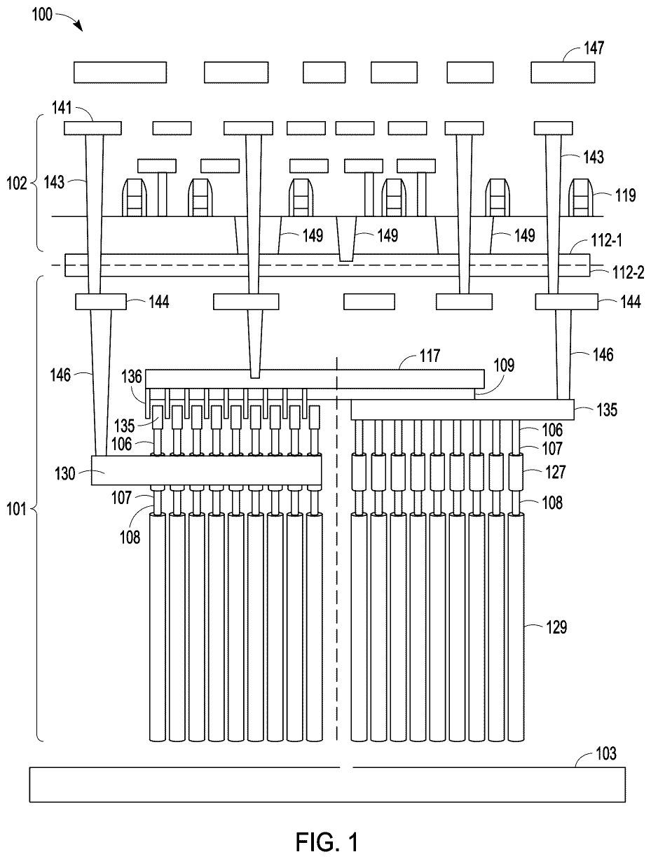

FIG. 1 illustrates a cross-sectional view of a representation of components of a DRAM 100 having a CoA architecture, where memory cells of the array can include a GAA transistor coupled to a capacitor. One of similar multiple features in FIG. 1 and in subsequent figures may be labelled without labeling all similar features, for ease of presentation. The memory cells can be structured as GAA 4F² hexagonal cells. The CoA architecture can include a control circuitry wafer 102 over an array wafer 101. Control circuitry wafer 102 can be located over array wafer 101 by a bonding layer 112-1 in control circuitry wafer 102 interfacing with a bonding layer 112-2 in array wafer 101. Bonding layer 112-1 and bonding layer 112-2 can be oxide layers such as, but not limited to, silicon oxide layers. Bonding layer 112-1 and bonding layer 112-2 can be a single bonding layer formed to control circuitry wafer 102 or formed to array wafer 101. Array wafer 101 can include a carrier portion 103 above which capacitors 129 are located or can include carrier portion 103 as a carrier wafer to which the module of capacitors 129 is bonded.

Control circuitry wafer 102 can include a number of transistors 119. Some of transistors 119 can include the transistors arranged as CMOS devices. Transistors 119 can be arranged above bonding layer 112-1 by isolation regions 149. The isolation regions can be dielectrics such as dielectric oxides, dielectric nitrides, or combinations of dielectric oxides and dielectric nitrides. Control circuitry wafer 102 can include a number of metallization lines as illustrated by metal lines 141 and 147. Metal lines 147 and 141 represent illustrations of metal lines routed in a direction in and out of the plane of the view of FIG. 1. Metal line 147 is a 1^{st} metal layer of a back end of line (BEOL) processing. Metal line 141 is a 0^{th} level metal layer ensuring that bonding contacts are routed to the appropriate circuits at the top of wafer 102. BEOL is a portion of an IC fabrication process that is typically directed to interconnecting individual devices of the IC with conductive paths such as, but not limited to, conductive traces or wires. The conductive traces or wires can include metals such as, but not limited to, copper, aluminum, ruthenium, or tungsten. The temperatures used in BEOL-compatible procedures can be substantially lower than temperatures used in constructing active devices of an IC in front end of line (FEOL) processing. Control circuitry wafer 102 can include a number of bonding contacts 143 to provide electrical signal paths from and through control circuitry wafer 102 to array wafer 101 and provide contacts through the wafer bonding of these two wafer portions. Bonding contacts 143 are structured through the bonding interface between control circuitry wafer 102 and array wafer 101, anchoring the bonded wafers together.

In FIG. 1, two views of array wafer 101 are shown, where the view to the left side of the dotted line is along an access line (WL) 130 and the view to the right side of the dotted line is along a digit line (BL) 135. Examples of WLs include word lines and digit lines include bit lines. Bonding contacts 143 from control circuitry wafer 102 can connect to landing pads 144 of array wafer 101. In the left side view, landing pads 144 are coupled to WL 130 by a line contact 146. WL 130 is coupled to transistors having all-around gates 127 and active area 106 (source/drain) and active area 108 of channel 107, where channel 107 can be provided as a pillar configuration. WL 130 can be integrated with all-around gates 127 for the GAA transistors to which WL is coupled, where the all-around gates 127 can be coupled to channels 107 by dielectrics. In the cross-sectional view of FIG. 1, only one WL 130 of multiple WLs of DRAM 100 is shown. Each active area 106 is coupled to an individual BL 135 and each active area 108 is coupled to an individual capacitor 129. In the cross-sectional view of FIG. 1, only one BL 135 of multiple BLs of DRAM 100 is labelled. BLs 135 are separated from adjacent ones of the BL 135 by shield lines 136 that are conductive, where shield lines 136 are separated from each other by dielectric material. Shield lines 136 can be metallic shield lines. Shield lines 136 can extend vertically from a body shield 117. Body shield 117 can be implemented as a conductive plate. Body shield 117 can be a metal plate-like structure. A buried dielectric 109 can be positioned between body shield 117 and BLs 135.

In the right side view, landing pads 144 are coupled to BL 135 by a line contact 146. In this right side view, WL 130 is not shown in this plane. The GAA transistors having all-around gates 127 and active areas 106, 108 can be constructed as thin film transistors (TFTs). TFTs are a class of metal-oxide-semiconductor field-effect transistors (MOSFETs). The GAA transistors can be structured as nanowires in a vertical direction. The GAA transistors can be structured as appropriately doped silicon such as appropriately doped epitaxial silicon.

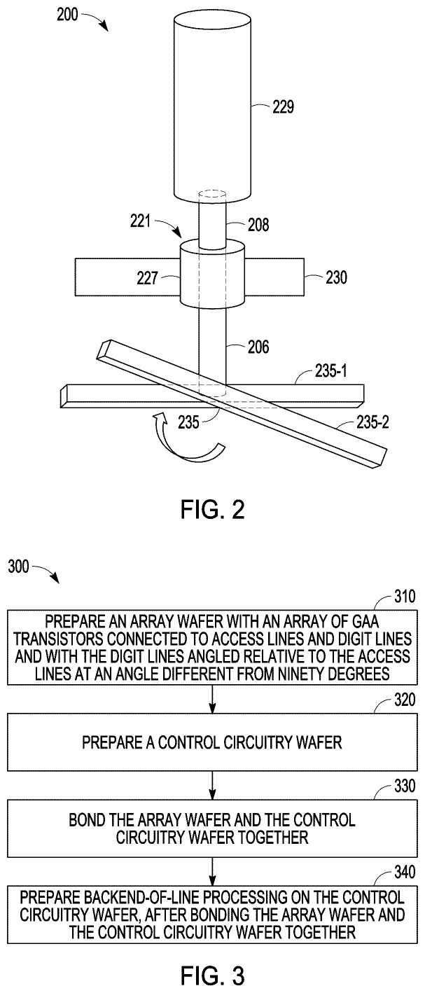

FIG. 2 is a presentation of an arrangement of a memory cell 200 having an access transistor 221 and a capacitor 229 that can be implemented in DRAM 100 of FIG. 1. Access transistor 221 can include an all-around gate 227 about a channel structure in a vertical pillar having a first active region 206 and a second active region 208. The vertical pillar can be a nanowire. All-around gate 227 is connected to a WL 230. Material of WL 230 can be integrated with material of all-around gate 227. Alternatively, WL 230 can contact all-around gate 227 at a position at the top of all-around gate 227 or at a position at the bottom of all-around gate 227. Second active region 208 can couple to capacitor 229 at a junction contact and second active region 206 can couple to a BL 235 at a junction contact to BL 235. FIG. 2 illustrates that BL 235 can have one of different orientations with respect to WL 230 and the vertical pillar containing first active region 206 and second active region 208, such as, but not limited to orientations 235-1 and 235-2. In a projection onto a common plane, orientation 235-2 can be oriented as angled relative to WL 230, which can be an angle different from ninety degrees. For example, the angle can be, but is not limited to, sixty degrees.

FIG. 3 is a flow diagram of features of an embodiment of an example method 300 of forming a memory device. Example method 300 can be used to fabricate DRAM 100 of FIG. 1. At 310, an array wafer is prepared. Preparation of the array wafer includes forming an array of GAA transistors connected to WLs and BLs. The BLs can be angled relative to the WLs at an angle different from ninety degrees. The array of GAA transistors can be formed as hexagonal memory cells in a 4F² architecture.

At 320, a control circuitry wafer is prepared. Preparation of the control wafer can include forming sense amplifiers (SAs) or sub-word line drivers (SWDs) for the memory array. At 330, the array wafer and the control circuitry wafer are bonded together. Various contacts connecting the memory arrays of the array wafer to upper circuits of the control circuitry wafer can be patterned. For example, the patterning of contacts can include one or more SAs to BLs or one or more SWDs to one or more WLs. At 340, BEOL processing on the control circuitry wafer is preformed, after bonding the array wafer and the control circuitry wafer together.

Variations of method 300 or methods similar to method 300 can include a number of different embodiments that may be combined depending on the application of such methods and/or the architecture of systems including a memory device for which such methods are implemented. Such methods can include forming the GAA transistors as thin film transistors.

Variations of method 300 or methods similar to method 300 can include conducting the preparation of the array wafer with a number of process procedures after forming the GAA transistors and WLs to the GAA transistors. Capacitors can be formed coupled vertically to the GAA transistors, after which the array wafer can be flipped and bonded to a carrier wafer. The carrier wafer can be thinned. The digital lines can be coupled to the capacitors, with shield lines formed between the BLs.

Variations of method 300 or methods similar to method 300 can include forming bonding interconnects in preparation for the bonding of the array wafer and the control circuitry wafer together. In preparation of the control circuitry wafer, bonding contacts can be formed to couple to the bonding interconnects. Bonding the array wafer and the control circuitry wafer together can include fusing an oxide region on the array wafer together with an oxide region on the control circuitry wafer. Other bonding techniques can be used.

Variations of method 300 or methods similar to method 300 can include forming bonding interconnects between the WLs on the array wafer and SWDs on the control circuitry wafer through triangle WL socket structures placed at the edge of an array patch of the memory device. Variations can include aligning one or more SA circuits on the control circuitry wafer over BL sockets placed on the array wafer and aligning one or more SWD circuits on the control circuitry wafer over WL sockets on the array wafer. Variations can include distributing BL connections and WL connections within BL-exit socket areas and WL-exit socket areas efficiently to reduce the interconnect parasitics and congestions.

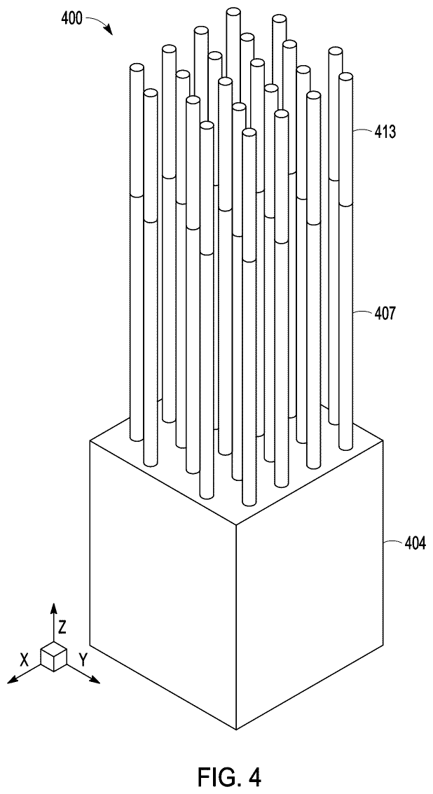

FIGS. 4-24 illustrate an example embodiment of an example method of forming a memory device having an array of hexagonal memory cells in a wafer-to-wafer interconnect architecture such as DRAM 100 of FIG. 1. Wafer-to-wafer interconnect architectures can include a wafer-on-wafer architecture. The memory cells can be arranged with a 4F² architecture. For the procedures discussed herein, the selection of processing materials can depend on the materials selected to form various components of and contacts to components of the memory device. The processing materials can be selected to allow removal of one or more materials, while retaining one or more other materials. In addition, deposition techniques can be used that are typical for the material being formed, the dimensions of the material being formed, and the architecture in which the material is being formed.

FIG. 4 shows a structure 400 after pillars 407 have been formed from a wafer 404. Pillars 407 can be formed in a subtractive process, where a substrative process includes removing material from a solid block of starting material. Pillars 407 can be silicon or epitaxial silicon. A hard mask 413 has been formed on a top portion of pillars 407. A hard mask is a material that can be used as a etch mask in an etch process, where the material is different from a polymer or other relatively soft material such as relatively soft resist materials. A hard mask is typically a high-density material used in the etch process to protect certain areas of a structure being processed from the etching chemicals being used in the etch process.

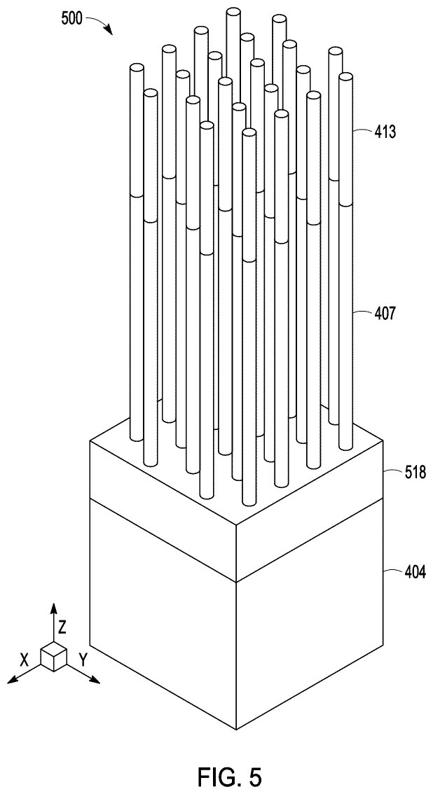

FIG. 5 shows a structure 500 after processing structure 400 of FIG. 4. A dielectric 518 has been formed on wafer 404 around the bottom of pillars 407. Dielectric 518 can be an oxide such as but not limited to silicon oxide. Dielectric 518 provides an insulation to a region that will be junctions of active areas of GAA transistors formed using pillars 407.

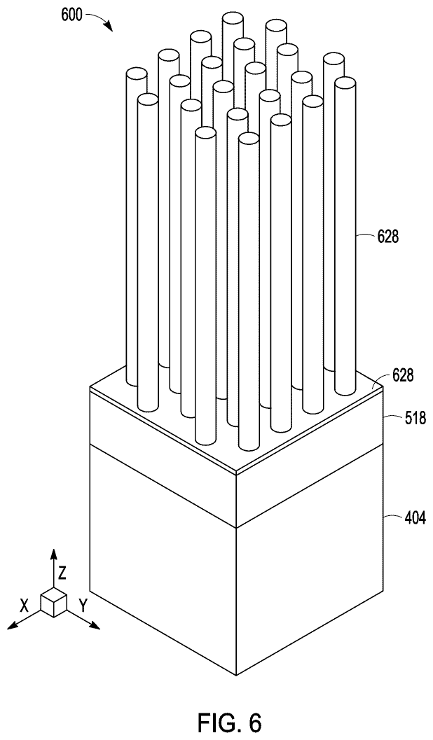

FIG. 6 shows a structure 600 after processing structure 500 of FIG. 5. A dielectric 628 has been deposited on hard mask 413, pillars 407, and dielectric 518 of structure 500. Portions of dielectric 628 will provide a gate dielectric for GAA transistors being formed. Dielectric 628 can be an oxide, such as but not limited to, silicon oxide.

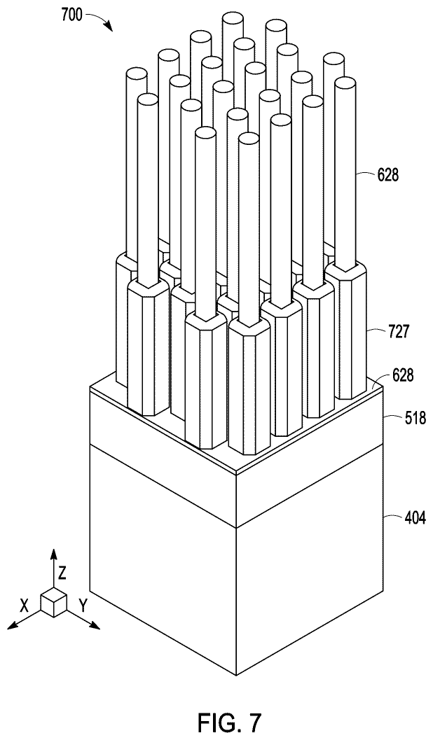

FIG. 7 shows a structure 700 after processing structure 600 of FIG. 6. Conductive material has been formed on dielectric 628 and the conductive material has been recessed, leaving conductive material for gates 727 of GAA transistors with pillars 407 covered with dielectric 628 extending above conductive material for gates 727. The conductive material can be formed by an appropriate deposition technique, which can be chemical vapor deposition (CVD) or atomic layer deposition (ALD). The conductive material for gates 727 can be metallic material.

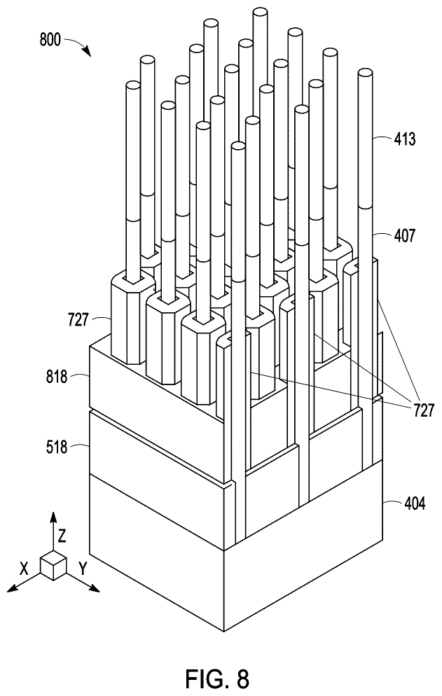

FIG. 8 shows a structure 800 after processing structure 700 of FIG. 7. A dielectric has been formed providing an insulation for WLs and recessed, leaving dielectric region 818 about conductive material for gates 727. The formation of the dielectric material can be formed by an appropriate deposition technique. Dielectric region 818 can be an oxide region such as, but not limited to, a silicon oxide region, or other appropriate dielectric for the memory device being formed. In the recess process, pillars 407 and mask 413 have been exposed above conductive material for gates 727. Optionally, exposure of pillars 407 and mask 413 can be conducted in the formation of structure 700. Though not shown, dielectric 628 remains around pillars 407 that are surrounded by conductive material for gates 727.

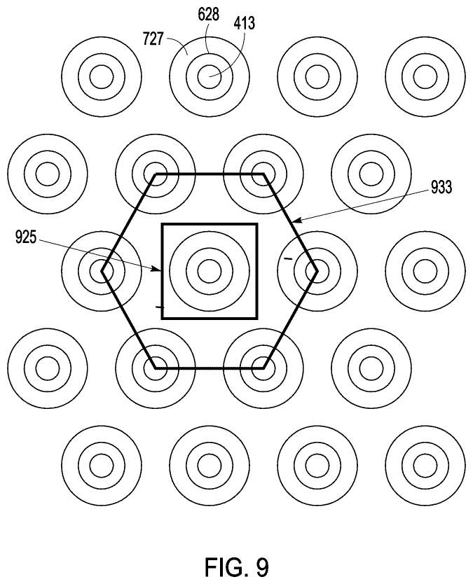

FIG. 9 shows a top view of structure 800 of GAA transistors of memory cells 925 in an array of hexagonal memory cells. Each memory cell 925 includes pillar 407 covered by mask 413 in this view, dielectric 628 for a gate dielectric of the GAA transistor, and conductive material for gates 727. As shown, centers of directly adjacent memory cells surrounding a memory cell 925 form a hexagon 933 of connected vertices.

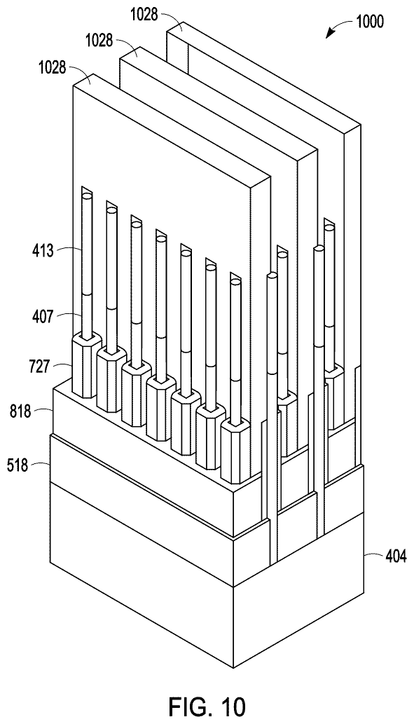

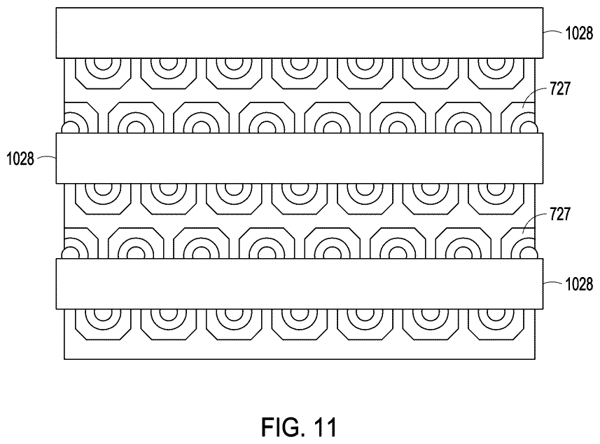

FIG. 10 shows a structure 1000 after processing structure 800 of FIG. 8. An underlayer 1028 for formation of WLs has been formed between rows of conductive material for gates 727. An underlayer is a carbon-based hard mask placed under photoresist. FIG. 11 is a top view of FIG. 10 showing underlayer 1028 between pairs of rows of conductive material for gates 727.

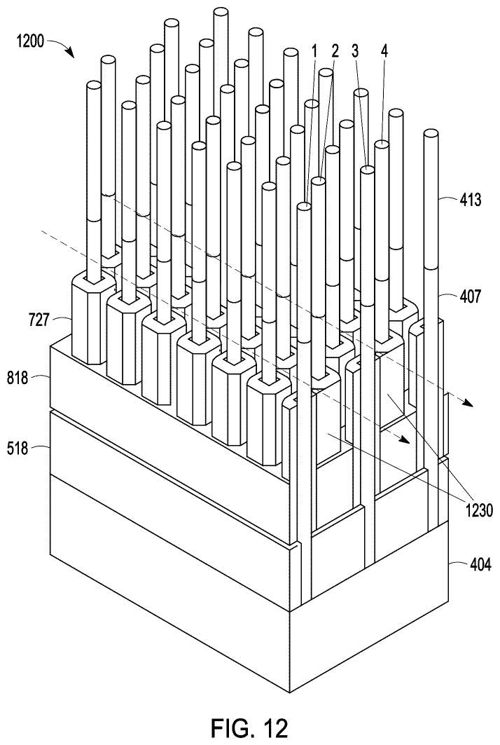

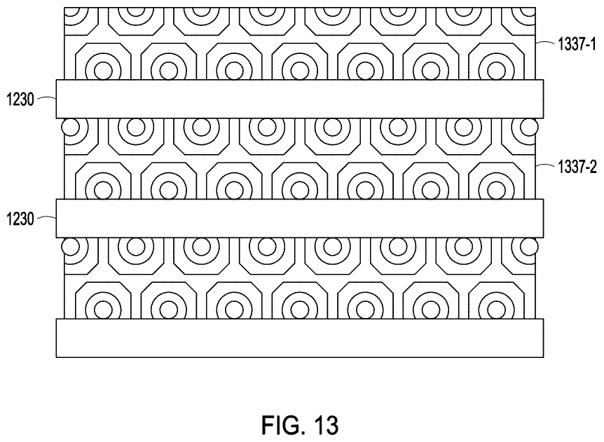

FIG. 12 shows a structure 1200 after processing structure 1000 of FIG. 10. Material to be used for WLs has been formed using underlayer 1028. The material can be formed by an appropriate deposition technique for the material and the memory device being formed. The material has been recessed, removing underlayer 1028 and leaving material for WLs 1230. Portions of pillars 407 and hard mask 413 have been exposed upon removing underlayer 1028. Material for WLs 1230 can be metallic material. In this view, first pillars 1, 2, 3, and 4 indicate rows of pillars 407, where the rows of pillars 407 are in the directions of the dotted lines. Material for WLs 1230 contacts pairs of rows of conductive material for gates 727, as shown in FIG. 13. Material for WLs 1230 are formed in the direction of the dotted line between row having first pillar 1 and adjacent row have first pillar 2. Material for WLs 1230 are formed in the direction of the dotted line between row having first pillar 3 and adjacent row have first pillar 4. FIG. 13 is a top view of structure 1200. Region 1337-1 shows a first side of GAA transistors being formed and a region 1337-2 shows a second side of the GAA transistors being formed. Use of the two sides of the conductive material for gates 727 can provide control to reduce WL resistance.

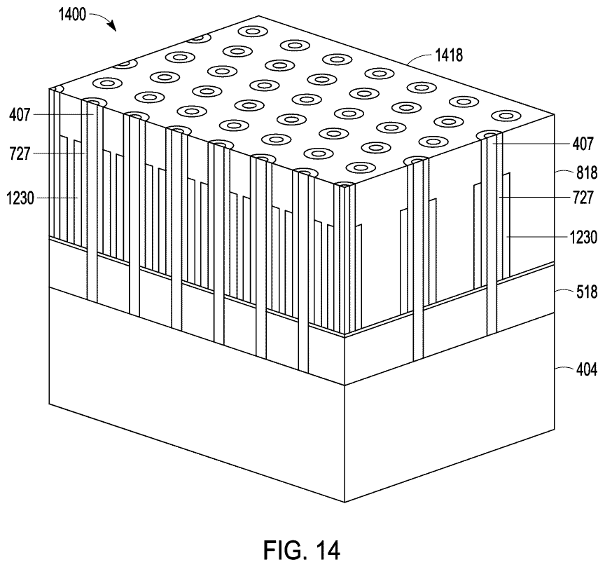

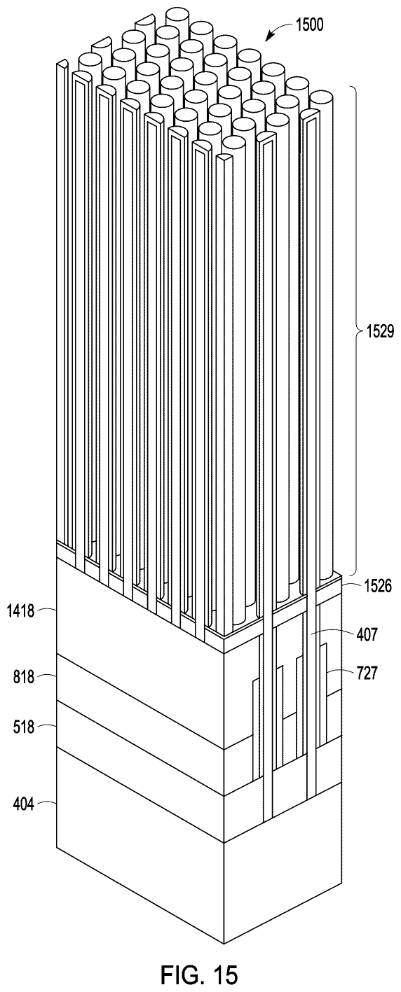

FIG. 14 shows a structure 1400 after processing structure 1200 of FIG. 12. A dielectric 1418 has been formed providing an insulation for WLs 1230. A chemical mechanical polishing (CMP) process has been applied, removing mask 413 and pillars 407 above a specified level for the top of dielectric 1418. The formation of the dielectric 1418 can be formed by an appropriate deposition technique. Dielectric 1418 can be an oxide region such as, but not limited to, a silicon oxide region or other appropriate dielectric for the memory device being formed. Portions of dielectric 628 separating pillar 407 and conductive material for gates 727 and providing a gate dielectric for conductive material for gates 727 are not shown or labelled in FIG. 14.

FIG. 15 shows a structure 1500 after processing structure 1400 of FIG. 14. A module of capacitors 1529 has been formed above a nitride stop region 1526 on the top surface of structure 1400. The capacitor formation of this process flows allows the use of redistribution layers (RDLs) to be skipped. A typical DRAM uses RDL interconnect to rotate cell contact to a hexagonal form for a capacitor to land on. A capacitor is preferred in hexagonal form, because it has the highest surface area (hence the storage capacity) when it is hexagonal. Having a hexagonal active area, removes the need for patterning a hexagonal RDL module. Avoidance of the use of a number of RDLs can provide cost reduction in fabrication of a memory device.

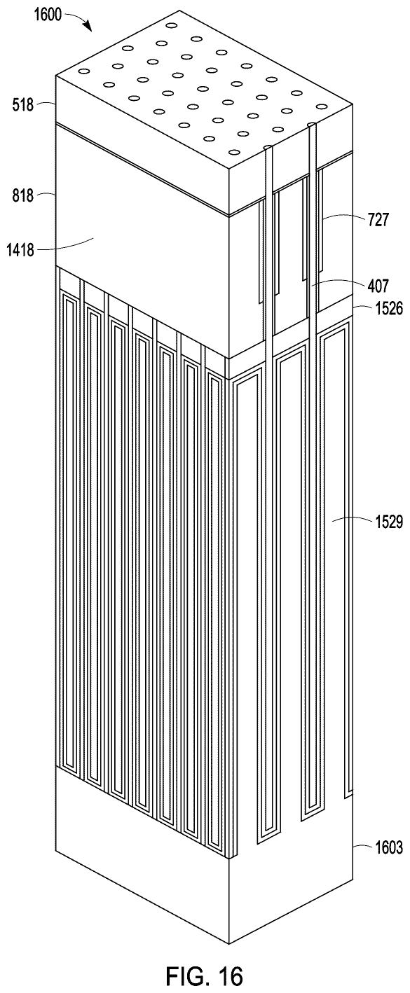

FIG. 16 shows a structure 1600 after processing structure 1500 of FIG. 15. Structure 1500 has been flipped and bonded to carrier wafer 1603 to form structure 1600. The flipped and bonded structure has been subjected to a CMP process.

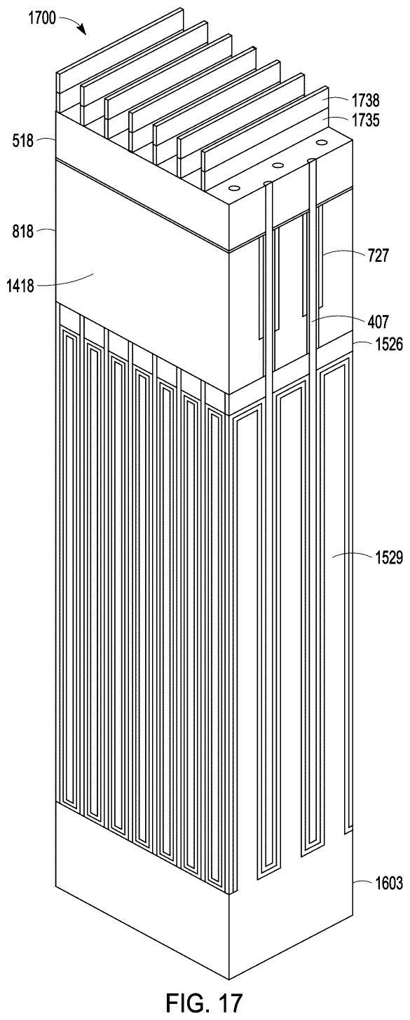

FIG. 17 shows a structure 1700 after processing structure 1600 of FIG. 16. BLs 1735 have been formed and patterned on the top of structure 1600. Formation of BLs 1735 can include use a subtractive process. A hard mask 1738 has been formed on each of BLs 1735. Hard mask 1738 has been used to pattern BLs 1735. Hard mask 1738 can be patterned together with the material for BL 1735 metal during the subtractive process. Hard mask 1738 can be, but is not limited to, a nitride hard mask. The pattern of BLs 1735 and hard mask 1738 has been formed with spaces between BLs 1735 and hard mask 1738. BLs 1735 can be formed by a deposition technique suitable for the material of the BLs and design of the memory device. BLs 1735 can be conductive lines such as, but not limited to, metal lines.

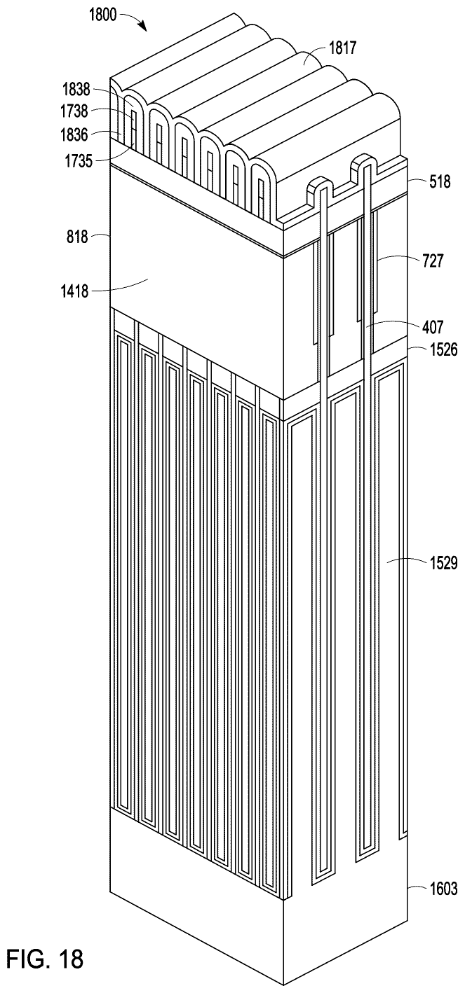

FIG. 18 shows a structure 1800 after processing structure 1700 of FIG. 17. After the patterning resulting in structure 1700, a dielectric spacer 1838 has been formed, which covers the sidewalls of BLs 1735 and is on top of hard mask 1738. Dielectric spacer 1838 can be, but is not limited to, an oxide formed by an appropriate deposition technique for the oxide. Dielectric spacer 1838 does not completely fill the space between the BLs 1735. Shield lines 1836 have been formed in the space between dielectric spacer 1838 covering the combinations of BLs 1735 and hard mask 1738 and have been formed vertically downward from a body shield 1817. Shield lines 1836 can be structured with the bottoms of shield lines 1836 aligned with the bottom of BLs 1735. Shield lines 1836 can be formed having a height equal to or greater than the height of the BLs 1735. Body shield 1817 can be formed above hard mask 1738 of the combinations. Shield lines 1836 can be conductive shield lines, such as, but not limited to, metal shield lines. Body shield 1817 can be formed as a conductive plate-like structure, such as, but not limited to, a metal plate-like structure. The material for body shield 1817 can be identical or similar to the material for shield lines 1836. Shield lines 1836 and body shield 1817 can be formed using a deposition technique appropriate for the conductive material used for these structures.

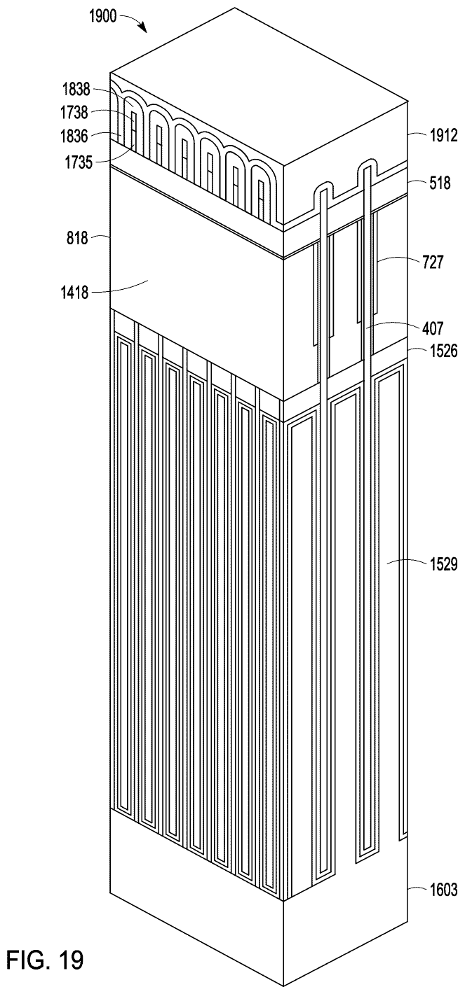

FIG. 19 shows a structure 1900 after processing structure 1800 of FIG. 18. A bonding layer 1912 has been formed on the top of structure 1900. Bonding layer 1912 can be an oxide layer, such as, but not limited to, silicon oxide. Bonding layer 1912 can be formed by a deposition technique suitable for the material for bonding layer 1912. With the bonding layer 1912 formed, structure 1900 is ready to be bonded to the top of a control circuitry wafer, with the control circuitry wafer on top of structure 1900 with the module of capacitors 1529 extending downward as shown in FIG. 1.

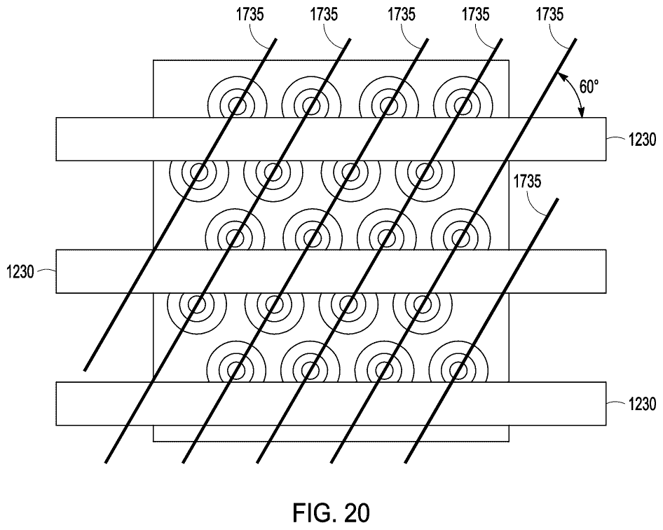

FIG. 20 shows a representation of a view of an array wafer 2001 as a bottom wafer that can be arranged similar to array wafer 101 of FIG. 1, which is a bottom wafer of DRAM 100, and can be processed according to procedures associated with FIGS. 4-19. Though multiple transistors are represented, only one transistor 2021 is labelled for ease of presentation. The top view illustrates BLs 1735 of FIGS. 17-19 constructed angled relative to material for WLs 1230 of FIGS. 12 and 14 at an angle different from ninety degrees. BLs 1735 can be constructed angled at, but not limited to, 60° relative to material for WLs 1230. Centers of BLs 1735 can be aligned with the center of active areas of transistors 2021 for memory cells. BLs 1735 are not shared with an adjacent transistor 2021. Material for WLs 1230, which can become WLs 130 such as WLs of FIG. 1, can be shared with adjacent transistors 2021, where each transistor 2021 can be associated with a bit. For example, all-around gates of transistors 2021 along one line of material for WLs 1230 can be integrated material with the one line of material for WLs 1230. Centers of material for WLs 1230 can be aligned at the middle of two adjacent transistors 2021.

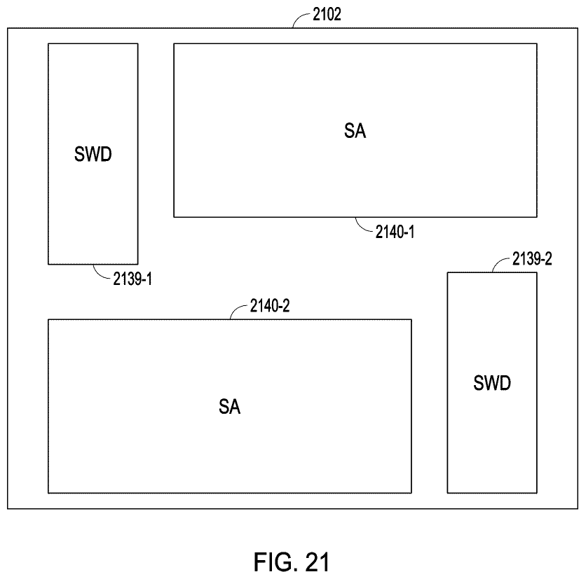

FIG. 21 shows a representation of a view of a control circuitry wafer 2102 as a top wafer that can be arranged similar to control circuitry wafer 102 of FIG. 1, which is a top wafer of DRAM 100. Control circuitry wafer 2102 can include a SWD 2139-1, a SWD 2139-2, a SA 2140-1, and a SA 2140-2. Control circuitry wafer 2102 can be bonded on top of array wafer 2001 of FIG. 20, with SWD 2139-1 and SWD 2139-2 aligned with selected lines of material for WLs 1230, and SA 2140-1 and SA 2140-2 aligned with selected lines of BLs 1735. The wafer-to-wafer arrangement of control circuitry wafer 2102 together with array wafer 2001 with angled BLs 1735 can include exits between wafers at selected ones of triangles 2034 that provides interconnect distribution.

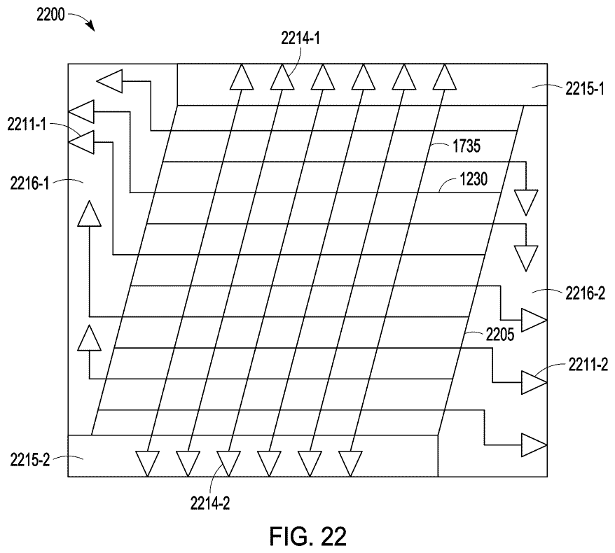

FIG. 22 shows a representation 2200 for connections of an array core in a wafer-to-wafer arrangement of control circuitry wafer 2102 of FIG. 21 together with array wafer 2001 of FIG. 20. An array core is a sub-array of memory cells of a memory array of a memory, where the sub-array is associated with one or more SWDs for the WLs for the sub-array and one or more SAs for the BLs for the sub-array. The memory array can be constructed with one or more sub-arrays. The array core can be arranged with SAs along one axis relative to the sub-array and SWDs arranged along the other direction. Representation 2200 shows a patch 2205 for the angled arrangement of BLs 1735 and WLs 1230 for a sub-array of memory cells that can be implemented in array wafer 2001. A patch can also be referred to as a mat. Patch 2205 in array wafer 2001 can be positioned under the components SWDs 2139-1 and 2139-2 and SAs 2140-1 and 2140-2 of control circuitry wafer 2102. Patch 2205 can be arranged with BL socket areas 2215-1 and 2215-2 along one axis direction and WL socket areas 2216-1 and 2216-2 along the other axis direction in this two-dimensional view.

BL socket area 2215-1 can include interconnects for BLs 1735 of array wafer 2001 to SA 2140-1 of control circuitry wafer 2102. The interconnects can include triangle BL sockets 2214-1 at an edge of array patch 2205. BL socket area 2215-2 can include interconnects for BLs 1735 of array wafer 2001 to SA 2140-2 of control circuitry wafer 2102. The interconnects can include triangle BL sockets 2214-2 at an edge of array patch 2205. WL socket area 2216-1 can include interconnects for WLs 1230 of array wafer 2001 to SWD 2139-1 of control circuitry wafer 2102. The interconnects can include triangle WL sockets 2211-1 at an edge of array patch 2205. WL socket area 2216-2 can include interconnects for WLs 1230 of array wafer 2001 to SWD 2139-2 of control circuitry wafer 2102. The interconnects can be triangle WL sockets 2211-2 at an edge of array patch 2205. With BLs 1735 formed as BLs 135 and WLs 1230 formed as WLs 130 of DRAM 100 of FIG. 1, triangle BL sockets 2214-1 and 2214-2 and WL sockets 2211-1 and 2211-2 can provide connections with line contacts 146, landing pads 144, bonding contacts 143, and metal lines 141 of DRAM 100. Forming triangle WL sockets and BL sockets at edges of an array patch can be conducted when preparing the array wafer, which can be prepared before preparing the control circuitry wafer in a fabrication process flow.

Various deposition techniques for components in the process flows discussed herein can be used that are typical for the material being formed, the dimensions of the material being formed, and the architecture in which the material is being formed in the fabrication of the memory device. Material and structures can be formed by a suitable process such as, but not limited to, a deposition process including, but not limited to, physical vapor deposition (PVD), CVD, ALD, or other deposition process. Other processes can be used. Selective etching can be used to remove selected regions in the processing discussed with respect to the process flows. Selective etching is a process in which one or more materials are removed from a structure, while one or more other materials remain in the structure with no or little removal. Selective etching can depend on the material to be etched, the material not to be etched, the etchant employed, and the method for etching. Types of etching include wet etching and dry etching, where each of these two basic methods include a number of different etching procedures. In addition, conventional masking techniques, providing protective regions in the processing, can be used in removal of selected regions in forming the components of the memory device.

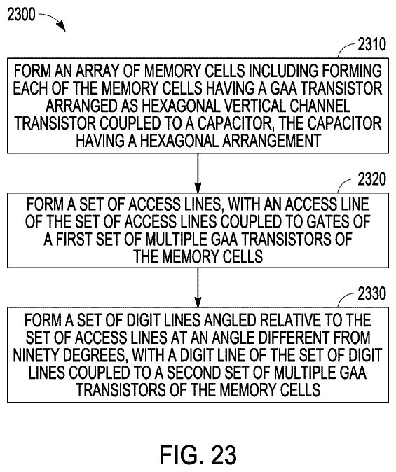

FIG. 23 is a flow diagram of features of an embodiment of an example method 2300 of forming a memory device. At 2310, an array of memory cells is formed. Each memory cell of the array is formed having a gate-all-around (GAA) transistor arranged as hexagonal vertical channel transistor coupled to a capacitor, where the capacitor has a hexagonal arrangement.

At 2320, a set of WLs is formed. A WL of the set of WLs is coupled to gates of a first set of multiple GAA transistors of the memory cells.

At 2330, a set of BLs is formed angled relative to the set of WLs at an angle different from ninety degrees. The angle can be, but is not limited to, sixty degrees. A BL of the set of BLs is coupled to a second set of multiple GAA transistors of the memory cells.

Variations of method 2300 or methods similar to method 2300 can include a number of different embodiments that may be combined depending on the application of such methods and/or the architecture of systems including a memory device for which such methods are implemented. Such methods can include forming control logic, decoders, drivers, and sensing circuitry above the array.

Variations of method 2300 or methods similar to method 2300 can include forming metal shield lines between adjacent BLs in the set of BLs. The metal shield lines can be formed extending vertically from a metal body shield.

Variations of method 2300 or methods similar to method 2300 can include forming vertical nanowires extending above a substrate, where the vertical nanowires can be structured having channel structures around which gates of the GAA transistors are formed.

In various embodiments, a memory device can comprise an array of memory cells, with each of the memory cells having a GAA transistor arranged as hexagonal vertical channel transistor coupled to a capacitor, where the capacitor has a hexagonal arrangement. The memory device can include a set of WLs, where a WL of the set of WLs is coupled to gates of a first set of multiple GAA transistors of the memory cells. The memory device can include a set of BLs, where a BL of the set of BLs is coupled to a second set of multiple GAA transistors of the memory cells. The set of BLs can be angled relative to the set of WLs at an angle different from ninety degrees.

Variations of such a memory device and its features, as taught herein, can include a number of different embodiments and features that can be combined depending on the application of such memory devices, the format of such memory devices, and/or the architecture in which such memory devices are implemented. Variations of such memory devices can include control logic and sensing circuitry above the array. The control logic and sensing circuitry and the array of memory cells can be arranged in a wafer-to-wafer interconnect architecture. Wafer-to-wafer interconnect architectures can include a wafer-on-wafer architecture.

Variations of such a memory device and its features can include shield lines between adjacent BLs in the set of BLs. The shield lines can extend vertically from a body shield. Variations can include a channel structure and active areas of the GAA transistor structured in a vertical nanowire. Variations can include the digit lines located on a side of a dielectric region opposite a side of the dielectric region on which the access lines are placed, the dielectric region can contain vertical channels structured as pillars of epitaxial semiconductor material. Variations of such a memory device can include the array of memory cells having a 4F² cell configuration.

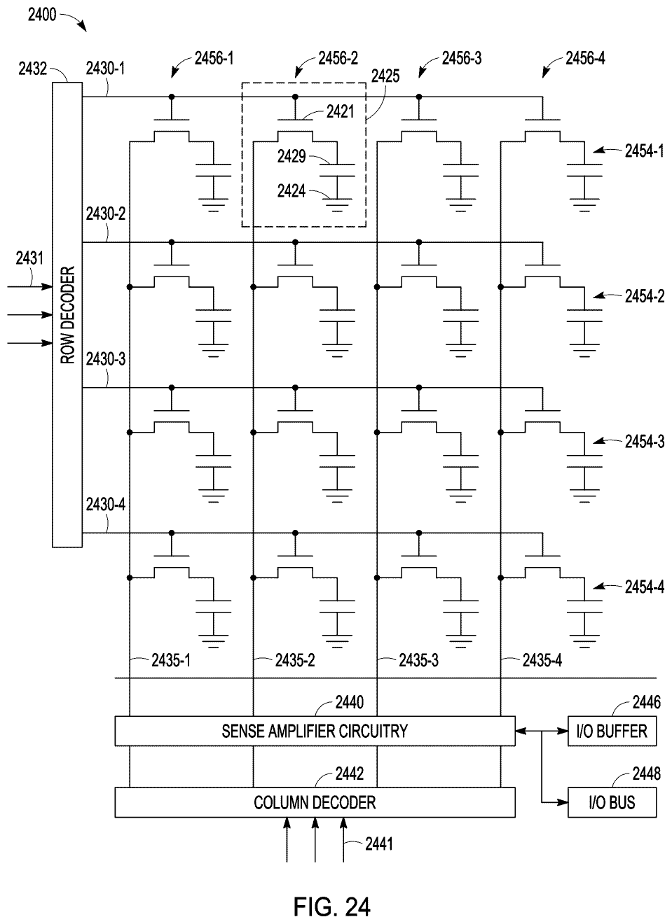

FIG. 24 is a schematic of an electrical arrangement of components of an embodiment of an example DRAM device 2400 that can include an architecture having an array of memory cells arranged as hexagonal cells, with each of the memory cells having a GAA transistor coupled to a capacitor, with the memory cells coupled to WLs and BLs, where the BLs are angled relative to the WLs at an angle different from ninety degrees, associated herein with respect to FIGS. 1-23. DRAM device 2400 can include an array of memory cells 2425 (only one being labeled in FIG. 24 for ease of presentation) arranged in rows 2454-1, 2454-2, 2454-3, and 2454-4 and columns 2456-1, 2456-2, 2456-3, and 2456-4. The physical orientation of the rows and columns is not shown. For simplicity and ease of discussion, the array is shown in only two dimensions, but the array can be extended into the third dimension. Further, while only four rows 2454-1, 2454-2, 2454-3, and 2454-4 and four columns 2456-1, 2456-2, 2456-3, and 2456-4 of four memory cells are illustrated, DRAM devices, like DRAM device 2400, can have significantly more memory cells 2425 (for example, tens, hundreds, or thousands of memory cells) per row or per column.

Each memory cell 2425 can include a single transistor 2421 and a single capacitor 2429, which is commonly referred to as a 1T1C (one-transistor-one capacitor cell). One plate of capacitor 2429, which can be termed the “node plate,” is connected to the drain terminal of transistor 2421, whereas the other plate of the capacitor 2429 is connected to ground 2424 or other reference node. Each capacitor 2429 within the array of 1T1C memory cells 2425 typically serves to store one bit of data, and the respective transistor 2421 serves as an access device to write to or read from storage capacitor 2429. Each transistor 2421 can be realized by a GAA nanowire transistor.

The transistor gate terminals within each row of rows 2454-1, 2454-2, 2454-3, and 2454-4 are portions of respective WLs 2430-1, 2430-2, 2430-3, and 2430-4, and the transistor source terminals within each of columns 2456-1, 2456-2, 2456-3, and 2456-4 are electrically connected to respective BLs 2435-1, 2435-2, 2435-3, and 2435-4. A row decoder 2432 can selectively drive the individual WLs 2430-1, 2430-2, 2430-3, and 2430-4, responsive to row address signals 2431 input to row decoder 2432. Row decoder 2432 can include one or more SWDs as well as the address decoder circuits. Driving a given WL at a high voltage causes the access transistors within the respective row to conduct, thereby connecting the storage capacitors within the row to the respective data lines, such that charge can be transferred between the data lines and the storage capacitors for read or write operations. Both read and write operations can be performed via SA circuitry 2440, which can transfer bit values between memory cells 2425 of the selected row of the rows 2454-1, 2454-2, 2454-3, and 2454-4 and input/output buffers 2446 (for write/read operations) or external input/output data buses 2448.

A column decoder 2442 responsive to column address signals 2441 can select which of the memory cells 2425 within the selected row is read out or written to. Alternatively, for read operations, the storage capacitors 2429 within the selected row can be read out simultaneously and latched, and the column decoder 2442 can then select which latch bits to connect to the output data bus 2448. Since read-out of the storage capacitors destroys the stored information, the read operation is accompanied by a simultaneous rewrite of the capacitor charge. Further, in between read/write operations, the capacitor charge is repeatedly refreshed to prevent data loss. Details of read/rewrite, write, and refresh operations are well-known to those of ordinary skill in the art.

DRAM device 2400 can be implemented as an IC within a package that includes pins for receiving supply voltages (for example, to provide the source and gate voltages for the transistors 2427) and signals (including data, address, and control signals). FIG. 24 depicts DRAM device 2400 in simplified form to illustrate basic structural components, omitting many details of the memory cells 2425 and associated WLs 2430-1, 2430-2, 2430-3, and 2430-4 and BLs 2435-1, 2435-2, 2435-3, and 2435-4 as well as the peripheral circuitry. For example, in addition to the row decoder 2432, column decoder 2442, SA circuitry 2440, and buffers 2446, DRAM device 2400 can include further peripheral circuitry, such as a memory control unit that controls the memory operations based on control signals (provided, for example, by an external processor), additional input/output circuitry, or other features associated with a memory device. Details of such peripheral circuitry are generally known to those of ordinary skill in the art and not further discussed herein. The peripheral circuitry can be located above the array of memory cells 2425 in a CoA architecture using a wafer-to-wafer interconnect architecture.

In two-dimensional (2D) DRAM arrays, the rows 2454-1, 2454-2, 2454-3, and 2454-4 and columns 2456-1, 2456-2, 2456-3, and 2456-4 of memory cells 2425 can be arranged along a single horizontal plane (i.e., a plane parallel to the layers) of the semiconductor substrate, for example, in a rectangular lattice with horizontal WLs 2430-1, 2430-2, 2430-3, and 2430-4 on one plane and angled BLs 2435-1, 2435-2, 2435-3, and 2435-4 on another plane. In 3D DRAM arrays, the memory cells 2425 can be arranged in a 3D lattice with a set of memory cells and associated WLs and BLs at a level above another set of memory cells and their associated WLs and BLs.

Memory devices having identical or similar features to example DRAM device 2400 and the structures associated with FIGS. 1-23 can be implemented in a variety of electronic devices. Electronic devices, such as mobile electronic devices (for example, smart phones, tablets, and other similar communication-related devices), electronic devices for use in automotive applications (for example, automotive sensors, control units, driver-assistance systems, passenger safety systems, comfort systems, or other similar systems), and internet-connected appliances or devices (for example, internet-of-things (IoT) devices, or other network-related devices), have varying storage needs depending on, among other things, the type of electronic device, use environment, performance expectations, or other criteria. Such electronic devices can be broken down into several main components: a processor (for example, a central processing unit (CPU) or other main processor); memory (for example, one or more volatile or nonvolatile RAM memory device, such as DRAM, mobile or low-power double-data-rate synchronous DRAM (DDR SDRAM), or other similar memory devices); and a storage device (for example, non-volatile memory (NVM) device, such as flash memory, ROM, a solid-state drive (SSD), a MultiMediaCard (MMC), other memory card structure or assembly, or other similar storage devices). In certain examples, electronic devices can include a user interface (for example, a display, touch-screen, keyboard, one or more buttons, or other similar interfacing structure), a graphics processing unit (GPU), a power management circuit, a baseband processor, one or more transceiver circuits, or other similar device. As used herein, “processor device” means any type of computational circuit such as, but not limited to, a microprocessor, a microcontroller, a graphics processor, a digital signal processor (DSP), or any other type of processor or processing circuit, including a group of processors or multi-core devices.

The following examples are example embodiments of devices and methods, in accordance with the teachings herein.

An example memory device 1 can comprise an array of memory cells, with each of the memory cells having a GAA transistor arranged as hexagonal vertical channel transistor coupled to a capacitor, the capacitor having a hexagonal arrangement; a set of WLs having a WL of the set of WLs coupled to gates of a first set of multiple GAA transistors of the memory cells; and a set of BLs having a BL of the set of BLs coupled to a second set of multiple GAA transistors of the memory cells, the set of BLs angled relative to the set of WLs at an angle different from ninety degrees.

An example memory device 2 can include features of example memory device 1 and can include control logic, decoders, drivers, and sensing circuitry above the array.

An example memory device 3 can include features of example memory device 2 and any of the preceding example memory devices and can include the control logic and sensing circuitry and the array of memory cells being arranged in a wafer-to-wafer interconnect architecture.

An example memory device 4 can include features of any of the preceding example memory devices and can include shield lines between adjacent BLs in the set of BLs.

An example memory device 5 can include features of example memory device 4 and any of the preceding example memory devices and can include the shield lines having a height equal to or greater than height of the BLs.

An example memory device 6 can include features of example memory device 4 and any of the preceding example memory devices and can include the shield lines extending vertically from a body shield.

An example memory device 7 can include features of any of the preceding example memory devices and can include the array of memory cells having a 4F² cell configuration.

An example memory device 8 can include features of any of the preceding example memory devices and can include a channel structure and active areas of the GAA transistor being structured in a vertical nanowire.

An example memory device 9 can include features of any of the preceding example memory devices and can include the digit lines are located on a side of a dielectric region opposite a side of the dielectric region on which the access lines are placed, the dielectric region containing vertical channels structured as pillars of epitaxial semiconductor material.

In an example memory device 10, any of the memory devices of example memory devices 1 to 9 may include memory devices incorporated into an electronic apparatus further comprising a host processor and a communication bus extending between the host processor and the memory device.

In an example memory device 11, any of the memory devices of example memory devices 1 to 10 may be modified to include any structure presented in another of example memory devices 1 to 10.

In an example memory device 12, any apparatus associated with the memory devices of example memory devices 1 to 11 may further include a machine-readable storage device configured to store instructions as a physical state, wherein the instructions may be used to perform one or more operations of the apparatus.

In an example memory device 13, any of the memory devices of example memory devices 1 to 12 may be formed in accordance with any of the below example methods 1 to 10 of forming a memory device or example methods 11 to 20 of forming a memory device.

An example method 1 of forming a memory device can comprise forming an array of memory cells including forming each of the memory cells having a gate-all-around (GAA) transistor arranged as hexagonal vertical channel transistor coupled to a capacitor, the capacitor having a hexagonal arrangement; forming a set of WLs having a WL of the set of WLs coupled to gates of a first set of multiple GAA transistors of the memory cells; and forming a set of BLs angled relative to the set of WLs at an angle different from ninety degrees, the set of digit lines having a BL of the set of BLs coupled to a second set of multiple GAA transistors of the memory cells.

An example method 2 of forming a memory device can include features of example method 1 of forming a memory device and can include forming control logic, decoders, drivers, and sensing circuitry above the array.

An example method 3 of forming a memory device can include features of any of the preceding example methods of forming a memory device and can include forming metal shield lines between adjacent BLs in the set of BLs.

An example method 4 of forming a memory device can include features of example method 3 of forming a memory device and any of the preceding example methods of forming a memory device and can include forming the metal shield lines to include forming the metal shield lines extending vertically from a metal body shield.

An example method 5 of forming a memory device can include features of any of the preceding example methods of forming a memory device and can include forming vertical nanowires extending above a substrate, with the vertical nanowires having channel structures around which gates of the GAA transistors are formed.

An example method 6 of forming a memory device can include features of any of the preceding example methods of forming a memory device and can include forming the BLs in a subtractive process.

An example method 7 of forming a memory device can include features of any of the preceding example methods of forming a memory device and can include forming the set of digit lines angled at sixty degrees relative to the set of access lines.

In an example method 8 of forming a memory device, any of the example methods 1 to 7 of forming a memory device may be performed in forming an electronic apparatus further comprising a host processor and a communication bus extending between the host processor and the memory device.

In an example method 9 of forming a memory device, any of the example methods 1 to 8 of forming a memory device may be modified to include operations set forth in any other of example methods 1 to 8 of forming a memory device.

In an example method 10 of forming a memory device, any of the example methods 1 to 9 of forming a memory device may be implemented at least in part through use of instructions stored as a physical state in one or more machine-readable storage devices.

An example method 11 of forming a memory device can include features of any of the preceding example methods 1 to 10 of forming a memory device and can include performing functions associated with forming any features of example memory devices 1 to 13.

An example method 12 of forming a memory device can comprise preparing an array wafer with an array of GAA transistors connected to WLs and BLs and with the BLs angled relative to the WLs at an angle different from ninety degrees; preparing a control circuitry wafer; bonding the array wafer and the control circuitry wafer together; and performing BEOL processing on the control circuitry wafer, after bonding the array wafer and the control circuitry wafer together.

An example method 13 of forming a memory device can include features of example method 12 of forming a memory device and can include forming the GAA transistors as thin film transistors.

An example method 14 of forming a memory device can include features of any of the preceding example methods 12 to 13 of forming a memory device and can include preparing the array wafer to include, after forming the GAA transistors and WLs to the GAA transistors: forming capacitors coupled vertically to the GAA transistors; flipping the array wafer and bonding the array wafer to a carrier wafer; thinning the carrier wafer; and forming the digital lines coupled to the capacitors, with shield lines between the BLs.

An example method 15 of forming a memory device can include features of any of the preceding example methods 12 to 14 of forming a memory device and can include preparing the array wafer to include forming bonding interconnects in preparation for the bonding of the array wafer and the control circuitry wafer together, and preparing the control circuitry wafer to include forming bonding contacts to couple to the bonding interconnects.

An example method 16 of forming a memory device can include features of any of the preceding example methods 12 to 15 of forming a memory device and can include forming an array patch having triangle WL sockets at an edge of the array patch.

An example method 17 of forming a memory device can include features of example method 16 of forming a memory device and any of the preceding example methods 12 to 15 of forming a memory device and can include forming bonding interconnects between the WLs on the array wafer and SWDs on the control circuitry wafer through the triangle WL socket structures placed at the edge of the array patch.

An example method 18 of forming a memory device can include features of any of the preceding example methods 12 to 17 of forming a memory device and can include bonding the array wafer and the control circuitry wafer together to include fusing an oxide region on the array wafer with an oxide region on the control circuitry wafer.

An example method 19 of forming a memory device can include features of any of the preceding example methods 12 to 18 of forming a memory device and can include bonding the array wafer and the control circuitry to include aligning one or more SA circuits on the control circuitry wafer over BL sockets placed on the array wafer, and aligning one or more SWD circuits on the control circuitry wafer over WL sockets on the array wafer.

An example method 20 of forming a memory device can include features of any of the preceding example methods 12 to 19 of forming a memory device and can include distributing BL connections and WL connections within BL-exit socket areas and WL-exit socket areas efficiently to reduce the interconnect parasitic and congestions.

An example method 21 of forming a memory device can include features of any of the preceding example methods 12 to 20 of forming a memory device and can include forming the array of GAA transistors as hexagonal memory cells in a 4F² architecture.

An example method 22 of forming a memory device can include features of example method 21 of forming a memory device and any of the preceding example methods 12 to 21 of forming a memory device and can include configuring the 4F² architecture as parallelogram having the angle between the BL and WL, which allows worldlines to be shared by adjacent GAA vertical transistors reducing the overall worldline resistance and enabling scaled or die size savings.

In an example method 23 of forming a memory device, any of the example methods 12 to 12 of forming a memory device may be performed in forming an electronic apparatus further comprising a host processor and a communication bus extending between the host processor and the memory device.

In an example method 24 of forming a memory device, any of the example methods 12 to 23 of forming a memory device may be modified to include operations set forth in any other of example methods 11 to 17 of forming a memory device.

In an example method 25 of forming a memory device, any of the example methods 12 to 24 of forming a memory device may be implemented at least in part through use of instructions stored as a physical state in one or more machine-readable storage devices.

An example method 26 of forming a memory device can include features of any of the preceding example methods 12 to 25 of forming a memory device and can include performing functions associated with any features of example memory devices 1 to 13.

An example method of operating a memory device can include performing functions associated with any features of example memory devices 1 to 13 and functions of memory devices formed by example methods 1 to 26.

An example machine-readable storage device storing instructions, that when executed by one or more processors, cause a machine to perform operations, can comprise instructions to perform functions associated with any features of example memory devices 1 to 13 or perform methods associated with any features of example methods 1 to 26 of forming a memory device.

Although specific embodiments have been illustrated and described herein, it will be appreciated by those of ordinary skill in the art that any arrangement that is calculated to achieve the same purpose can be substituted for the specific embodiments shown. Various embodiments use permutations and/or combinations of embodiments described herein. It is to be understood that the above description is intended to be illustrative, and not restrictive, and that the phraseology or terminology employed herein is for the purpose of description.

What is claimed is:

1. A memory device comprising:
an array of memory cells, with each of the memory cells having a gate-all-around (GAA) transistor arranged as hexagonal vertical channel transistor coupled to a capacitor, the capacitor having a hexagonal arrangement;
a set of access lines having an access line of the set of access lines coupled to gates of a first set of multiple GAA transistors of the memory cells; and
a set of digit lines having a digit line of the set of digit lines coupled to a second set of multiple GAA transistors of the memory cells, the set of digit lines angled relative to the set of access lines at an angle different from ninety degrees.

2. The memory device of claim 1, wherein the memory device includes control logic, decoders, drivers, and sensing circuitry above the array.

3. The memory device of claim 2, wherein the control logic and sensing circuitry and the array of memory cells are arranged in a wafer-to-wafer interconnect architecture.

4. The memory device of claim 1, wherein the memory device includes shield lines between adjacent digit lines in the set of digit lines.

5. The memory device of claim 4, wherein the shield lines extend vertically from a body shield.

6. The memory device of claim 1, wherein the array of memory cells has a 4F² cell configuration.

7. The memory device of claim 1, wherein a channel structure and active areas of the GAA transistor are structured in a vertical nanowire.

8. The memory device of claim 1, wherein the digit lines are located on a side of a dielectric region opposite a side of the dielectric region on which the access lines are placed, the dielectric region containing vertical channels structured as pillars of epitaxial semiconductor material.

9. A method of forming a memory device, the method comprising:
forming an array of memory cells including forming each of the memory cells having a gate-all-around (GAA) transistor arranged as hexagonal vertical channel transistor coupled to a capacitor, the capacitor having a hexagonal arrangement;
forming a set of access lines having an access line of the set of access lines coupled to gates of a first set of multiple GAA transistors of the memory cells; and
forming a set of digit lines angled relative to the set of access lines at an angle different from ninety degrees, the set of digit lines having a digit line of the set of digit lines coupled to a second set of multiple GAA transistors of the memory cells.

10. The method of claim 9, wherein the method includes forming control logic, decoders, drivers, and sensing circuitry above the array.

11. The method of claim 9, wherein the method includes forming metal shield lines between adjacent digit lines in the set of digit lines.

12. The method of claim 11, wherein forming the metal shield lines includes forming the metal shield lines extending vertically from a metal body shield.

13. The method of claim 9, wherein the method includes forming vertical nanowires extending above a substrate, with the vertical nanowires having channel structures around which gates of the GAA transistors are formed.

14. The method of claim 9, wherein the method includes forming the set of digit lines angled at sixty degrees relative to the set of access lines.

15. A method of forming a memory device, the method comprising:
preparing an array wafer with an array of gate-all-around (GAA) transistors connected to access lines and digit lines and having the digit lines angled relative to the access lines at an angle different from ninety degrees;
preparing a control circuitry wafer;
bonding the array wafer and the control circuitry wafer together; and
performing backend-of-line processing on the control circuitry wafer, after bonding the array wafer and the control circuitry wafer together.

16. The method of claim 15, wherein the method includes forming the GAA transistors as thin film transistors.

17. The method of claim 15, wherein preparing the array wafer includes after forming the GAA transistors and access lines to the GAA transistors:
forming capacitors coupled vertically to the GAA transistors;
flipping the array wafer and bonding the array wafer to a carrier wafer;
thinning the carrier wafer; and
forming the digital lines coupled to the capacitors, with shield lines between the digit lines.

18. The method of claim 15, wherein preparing the array wafer includes forming bonding interconnects in preparation for the bonding of the array wafer and the control circuitry wafer together, and preparing the control circuitry wafer includes forming bonding contacts to couple to the bonding interconnects.

19. The method of claim 15, wherein bonding the array wafer and the control circuitry wafer together includes fusing an oxide region on the array wafer with an oxide region on the control circuitry wafer.

20. The method of claim 15, wherein the method includes forming the array of GAA transistors as hexagonal memory cells in a 4F² architecture.
